(19) United States
(12) Patent Application Publication
(10) Pub. No.: US 2007/0012928 A1
(43) Pub. Date: Jan. 18, 2007

(54) Light emitting diode comprising semiconductor nanocrystal complexes and powdered phosphors

(76) Inventors: Zouyan Peng, Schenectady, NY (US); Michael Locascio, Clifton Park, NY (US); Kwang-Ohk Cheon, Latham, NY (US)

Correspondence Address: KENYON & KENYON LLP, 1500 K STREET N.W., SUITE 700, WASHINGTON, DC, 20005, US

(21) Appl. No.: 11/485,335

(22) Filed: Jul. 13, 2006

Related U.S. Application Data
(60) Provisional application No. 60/698,643, filed on Jul. 13, 2005.

(51) Int. Cl. H01L 33/00

(52) U.S. Cl. 257/79

(57) ABSTRACT

A white light light emitting diode (LED) formed by depositing an LED chip that emits light at a first wavelength and forming a semiconductor nanocrystal complex. The semiconductor nanocrystal complex absorbs at least a portion of the light emitted by the LED chip and emits light at a second wavelength. The semiconductor nanocrystal complex and a powdered phosphor are deposited over the LED chip. The powdered phosphor also absorbs a portion of the light emitted by the LED chip and emits light at a third wavelength. The semiconductor nanocrystal complex is selected to provide a color of the spectrum that is lacking from the combined output of phosphor/LED chip combination, to improve a Color Rating Index (CRI) value and to provide a “warmer” light. The semiconductor nanocrystal complex and the powdered phosphor can be mixed into the same matrix material or into separate matrix materials and/or deposited as separate layers.

### CROSS-REFERENCE TO RELATED APPLICATIONS

The present application claims priority to U.S. Provisional Application No. 60/698,643, filed Jul. 13, 2005, which is incorporated by reference herein.

### FIELD OF THE INVENTION

The present invention relates to light emitting diodes and particularly to light emitting diodes comprising semiconductor nanocrystal complexes. The present invention also relates to methods of making light emitting diodes comprising semiconductor nanocrystal complexes.

### BACKGROUND OF THE INVENTION

Semiconductor nanocrystals are typically tiny crystals of II-VI, III-V, IV-VI materials that have a diameter approximately between 1 nanometer (nm) and 20 nm. In the strong confinement limit, the physical diameter of the nanocrystal is smaller than the bulk excitation Bohr radius causing quantum confinement effects to predominate. In this regime, the nanocrystal is a 0-dimensional system that has both quantized density and energy of electronic states where the actual energy and energy differences between electronic states are a function of both the nanocrystal composition and physical size. Larger nanocrystals have more closely spaced energy states and smaller nanocrystals have the reverse. Because interaction of light and matter is determined by the density and energy of electronic states, many of the optical and electric properties of nanocrystals can be tuned or altered simply by changing the nanocrystal geometry (i.e., the physical size).

Single nanocrystals or monodisperse populations of nanocrystals exhibit unique optical properties that are size tunable. Both the onset of absorption and the photoluminescent wavelength are a function of nanocrystal size and composition. The nanocrystals will absorb all wavelengths shorter than the absorption onset, however, photoluminescence will always occur at the absorption onset. The bandwidth of the photoluminescent spectra is due to both homogeneous and inhomogeneous broadening mechanisms. Homogeneous mechanisms include temperature dependent Doppler broadening and broadening due to the Heisenburg uncertainty principle, while inhomogeneous broadening is due to the size distribution of the nanocrystals. The narrower the size distribution of the nanocrystals, the narrower the full-width half max (FWHM) of the resultant photoluminescent spectra. In 1991, Brus wrote a paper reviewing the theoretical and experimental research conducted on colloidally grown semiconductor nanocrystals, such as cadmium selenide (CdSe) in particular. (Brus, L., Quantum Crystallites and Nonlinear Optics, Applied Physics A, vol. 53 (1991). That research, precipitated in the early 1980's by the likes of Efros, Ekimov, and Brus himself, greatly accelerated by the end of the 1980's as demonstrated by the increase in the number of papers concerning colloidally grown semiconductor nanocrystals.

Drivers for the growth of high quality white LEDs include demand for large screen televisions, outdoor/landscape lighting luminaires, interior illumination in the transportation sector (e.g., airplanes, subways, ships, etc.), and in particular, automobiles. The demand for much higher quality white LEDs should begin to grow significantly in 2008, when automotive manufacturers have committed to introducing models with white LED forward lighting.

Since the commercialization of blue light emitting LEDs by Nichia in the mid-1990s, phosphor R&D programs at many companies have focused on re-examining their phosphor portfolios to discover materials that are compatible with V, violet and blue LED wavelengths. G E, Nichia, Osram (with its parent, Siemens, and with Symyx), Philips and Toyoda Gosei employ combinatorial analysis techniques to create, isolate and test phosphor materials and morphologies.

The first and most common method to achieve white light emission from an LED is to combine a powdered phosphor with a blue GaN LED. The phosphor acts to down convert the emission of the blue GaN LED. The LED is typically placed in a parabolic mirror and subsequently coated with a phosphor-containing epoxy. The blue light emitted from the LED is absorbed by the powdered phosphor and re-emitted as light at a longer wavelength, typically yellow. The blue light from the GaN LED and the generally yellow light from the phosphor combine to form white light. Yttrium aluminum garnet (YAG:Ce3+) is the most common phosphor for this application. A typical emission spectrum of the white light LEDs prepared by combining YAG with a blue light has two distinct peaks. Not surprisingly, the first peak corresponds to blue LED emission, ˜470 nm, and the second peak corresponds to the emission of the YAG phosphor, ˜555 nm.

Since a white LED device generates light by using one kind of light-emitting element (single-color), it is a general practice to use a single-color light emitting element in combination with a phosphor which can convert the wavelength of the light emitted from the light-emitting element to emit a light of a different color. Although these lights have proven to be relatively efficient, on the order of 25-30 lumens/Watt (l/W), the addition of a second phosphor would tend to decrease the efficiency of the lights.

A second problem associated with traditional white-light LEDs is that often the red light, the green light or the blue light is insufficient in the white LED that is obtained by combining a blue light-emitting element for emitting light having an excitation wavelength of YAG and the YAG phosphor. This leads to red, and matters displayed in red, looking subdued. This problem is often referred to as color rendering. Color rendering is an evaluation of how colors appear under a given light source. For example, a shade of red can be rendered more pink, more yellow, lighter or darker depending on the characteristics of the illumination falling on it.

One system being used today for describing color rendition was developed by the CIE (Commission Internationale De I'Eclairage), the International Lighting Standards Commission. The system is referred to as the Color Rendering Index or CRI. This method uses eight test colors and expresses the relative ability of the light source to render those eight colors as a standard reference illuminant would render those colors. The combination of YAG phosphor with a typical blue LED typically has a CRI of between 60 and 75. This combination is lacking in deep-red and cyan-green and therefore does not generate a “good” white light.

White light often has poor luminous efficacy. Luminous efficacy is the efficiency in lumens/Watt of the conversion from electrical power to optical power, combined with the efficiency of the conversion from optical power to luminous flux sensed by the eye within this range. Currently, the luminous efficacies for white light LEDs are of the order of 25 lumens/Watt. It is desired to produce an LED device of the present invention that maintains the luminous efficacy of existing white light LEDs while at the same time improving the CRI.

Visible light is often described by its color temperature. A light's color temperature is determined by comparing its hue with a theoretical, heated black-body radiator. The light's color temperature is the temperature in kelvins (K)at which the heated black-body radiator matches the hue of the lamp. An incandescent light is very close to being a black-body radiator. However, many other light sources, such as fluorescent lamps, do not emit radiation in the form of a black-body curve, and are assigned what is known as a correlated color temperature (CCT), which is the color temperature of a black body which most closely matches the lights emission curve. Blue is typically referred to as the “hotter” color even though its color temperature is lower than red. Many white light emitting LED devices have a CCT of over 7500 K, and it is desirable to have a warmer LED device (i.e., an LED with a lower CCT).

### BRIEF DESCRIPTION OF THE DRAWINGS

FIG. 1 is a schematic illustration of an LED according to an embodiment of the present invention.

FIG. 2 is a schematic illustration of an LED according to a second embodiment of the present invention.

FIG. 3 is a schematic illustration of a method of making an LED according to an embodiment of the present invention.

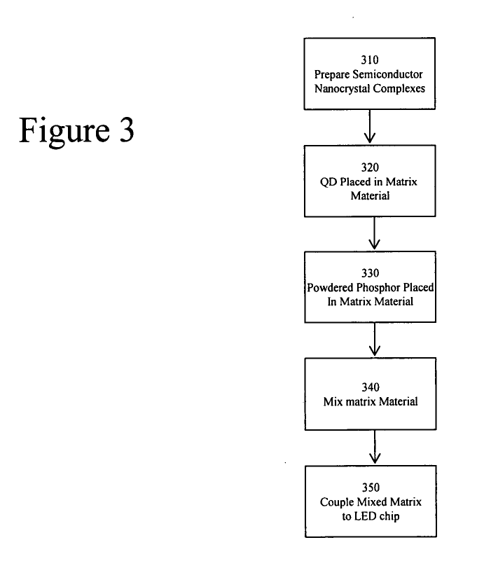

FIG. 4 provides a graph comparing the emission spectrum of three LED devices of the present invention with a standard black body emission.

### DETAILED DESCRIPTION OF THE INVENTION

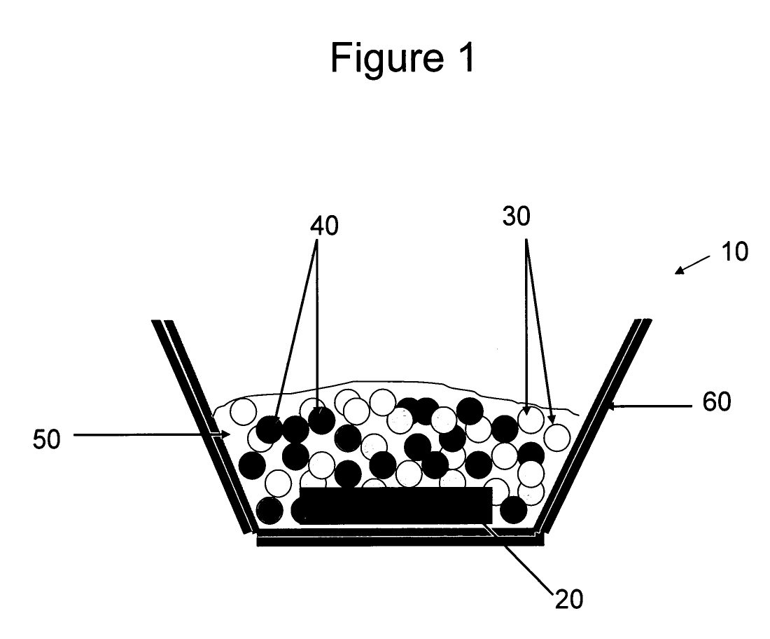

Referring to FIG. 1, in an embodiment, the present invention provides a white light emitting LED 10. The white light emitting LED 10 comprises an LED chip 20, a powdered phosphor 30, a semiconductor nanocrystal complex 40, a matrix material 50, and a housing 60.

Different LED chips 10 produce distinct colors. The color of the light emitted from LED chip 20 is dependent on the chip material used. Typically, LED chips are made from gallium-based crystals that contain one or more additional materials such as phosphorous. For example, AlInGaP and InGaN are used for creating high brightness LEDs in most colors from blue through red. The LED chip should be selected such that it emits light at an energy that is capable of exciting the semiconductor nanocrystal complex 40 and the powdered phosphor 30. In an embodiment of the present invention, the light emitted from the LED chip may be between 440 nm to 480 nm. It is appreciated that other LED chips may be used such as UV violet emitting chips.

The phosphor powder 30 absorbs the emission of the light emitted by the LED chip 20 and, typically, emits light at a wavelength different from the LED chip. The primary powdered phosphor 30 used for the creation of white light is YAG phosphor. Other non-limiting examples of phosphor powders include SPE, BAM, BAM-Mn, CBT, YOX and MGM. These phosphor powders are all capable of converting light from an LED chip to a second light of a longer wavelength.

Semiconductor nanocrystal complex 40 comprises a semiconductor nanocrystal core (also known as a semiconductor nanoparticle or semiconductor quantum dot) having an outer surface. A semiconductor nanocrystal core may comprise spherical nanoscale crystalline materials (although oblate and oblique spheroids can be grown as well as rods and other shapes) having a diameter of less than the Bohr radius for a given material and typically, but not exclusively, comprise II-IV, III-V, and IV-VI binary semiconductors. Non-limiting examples of semiconductor nanocrystal core include ZnS, ZnSe, ZnTe, CdS, CdSe, CdTe, HgS, HgSe, HgTe (II-VI materials), PbS, PbSe, PbTe (IV-VI materials), AlN, AlP, AlAs, AlSb, GaN, GaP, GaAs, GaSb, InN, InP, InAs, InSb (III-V materials). In addition to binary semiconductors, a semiconductor nanocrystal core may comprise ternary semiconductor materials. Non-limiting examples of ternary semiconductor materials include AxByC wherein A and/or B may comprise a group II, III, or IV element, C may comprise a group V or VI element, and x and y are molar fractions between 0 and 1. In addition to a semiconductor nanocrystal core the semiconductor nanocrystal complex may comprise either one or more metal layers or shell layers grown around the semiconductor nanocrystal cores.

The shells may provide for a type A semiconductor nanocrystal complex 40. Shells may comprise various different semiconductor materials such as, for example, CdSe, CdS, CdTe, ZnS, ZnSe, ZnTe, HgS, HgSe, HgTe, InP, InAs, InSb, InN, GaN, GaP, GaAs, GaSb, PbSe, PbS, and PbTe.

Semiconductor nanocrystal cores, metal layers and/or shells may be grown by the pyrolysis of organometallic precursors in a chelating ligand solution or by an exchange reaction using the prerequisite salts in a chelating ligand solution. The chelating ligands are typically lyophilic and have an affinity moiety for the metal layer and another moiety with an affinity toward the solvent, which is usually hydrophobic. Typical examples of chelating ligands include lyophilic surfactant molecules such as Trioctylphosphine oxide (TOPO), Trioctylphosphine (TOP), and Tributylphosphine (TBP).

Semiconductor nanocrystal complexes should be selected such that they absorb at least a portion of the light emitted by the LED chip and emit light at a second wavelength. Typically, white light LEDs made with YAG phosphor and InGaN LED chips lack light in the red wavelengths. To compensate for this deficiency, it has been found that CdSe core semiconductor nanocrystals with a shell of CdS/ZnS emitting at 600 nm to 650 nm are able to increase the CRI for these devices.

The semiconductor nanocrystal complex should be selected such that it replaces any deficiency in the powder phosphor and LED chip emission. As stated above, phosphors and LEDs typically have a single emission peak. Thus, when they are combined for the creation of white light the light is deficient in various areas of the spectrum. When combining powdered phosphor and the semiconductor nanocrystal complex, the semiconductor nanocrystal complex should be selected such that it will provide a color of the spectrum that is lacking in the traditional powdered phosphor/LED chip combination.

Phosphor 30 and semiconductor nanocrystal complex 40 are each placed in matrix material 50. Although FIG. 1 shows the phosphors and the semiconductor nanocrystal complexes in a single matrix, it is to be appreciated that different matrix materials may be used. Further, layers can be formed. For example, the phosphor powders in a first matrix material may be placed on top of the LED chip and then a second matrix material comprising the quantum dot complex 40 may be added onto the first matrix material comprising the phosphor powder.

Typical matrix materials into which the phosphor powder are mixed include organic and water based solvents into which a binding agent and an adhesive have been added. Example matrix materials that may be used in the present invention include, but are not limited to, urethane/acrylate, butyl acetate and xylol. Additionally, silicones, epoxies and polymers may be used as a matrix material.

Traditional white light emitting LEDs, comprising YAG phosphor and InGaN, have a CRI of approximately 70-80. The LEDs of the present invention improve the CRI of the phosphor LED chip combination they are being added to. The term “improved color rendering index” is used herein to indicate a color rendering index for an LED device comprising semiconductor nanocrystals that is greater than the light emitted by the mixture LED chip and powdered phosphor that they are used in combination with. Preferably, the improved color rendering index would be greater than 80, more preferably greater than 85 and most preferably greater than 90.

The addition of the semiconductor nanocrystal complexes of the present invention do not substantially reduce the efficiency of the underlying LED chip/powdered phosphor combination. The term “do not substantially reduce the efficiency of the underlying LED chip” is used herein to indicate that the addition of the nanocrystal complexes of the present invention decrease the deficiency of the underlying LED chip/phosphor combination by less than 30%, preferably less than 20%, more preferably less than 10%, most preferably less than 5%.

The addition of the semiconductor nanocrystal complex may not substantially increase the color temperature of the underlying device. Preferrably, the addition of the semiconductor nanocrystal complexes would decrease the color temperature of the device resulting in a “warmer” light.

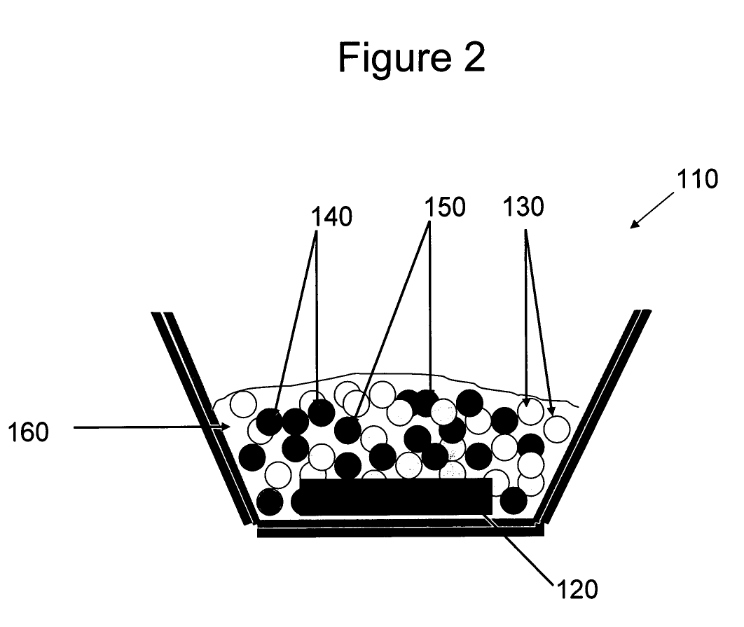

Referring to FIG. 2, in an embodiment, the present invention provides a white light emitting LED 110. The white light emitting LED 110 comprises an LED chip 120, a powdered phosphor 130, two or more semiconductor nanocrystal complexes 140, 150, a matrix material 160, and a housing 170. The LED chip 120 may be as described for LED chip 20 with respect to FIG. 1.

The phosphor powder 130 absorbs the emission of the light emitted by the LED chip 120 and, typically, emits light at a wavelength different from the LED chip. The phosphor powder may be as described for the phosphor powder 30 described with respect to FIG. 1.

Semiconductor nanocrystal complexes 140 and 150 comprise a semiconductor nanocrystal core (also known as a semiconductor nanoparticle or semiconductor quantum dot) having an outer surface. Semiconductor nanocrystal complexes 140 and 150 may be as described for the semiconductor nanocrystal complexes 40 of FIG. 1.

Semiconductor nanocrystal complexes 140 and 150 should each be selected such that they absorb at least a portion of the light emitted by the LED chip and emit light at a second wavelength. Since white light LEDs made with YAG phosphor and InGaN LED chips typically lack light in the red wavelengths and blue or green wavelengths depending on the underlying LED chip, CdSe semiconductor nanocrystals emitting at 600 nm to 650 nm and CdS (or CdSe) semiconductor nanocrystals emitting at 490-530 nm can be used to increase the CRI for these particular applications.

The semiconductor nanocrystal complexes 140 and 150 should be selected such that they replace any deficiency in the powder phosphor and LED chip emission. As stated above, phosphors and LEDs typically have a single emission peak. Thus, when they are combined for the creation of white light, the light is deficient in various areas of the spectrum. When combining powdered phosphor and the semiconductor nanocrystal complex, the semiconductor nanocrystal complexes should be selected such that they will provide two or more colors of the spectrum that is lacking in the traditional powdered phosphor/LED chip combination. Although the present embodiment is described with respect to the addition of two nanocrystal complexes, it is to be appreciated that 3 or more semiconductor nanocrystal complexes 140 and 150 may be combined to form the white light LEDs in accordance with the present invention.

Phosphor 130 and semiconductor nanocrystal complexes 140 and 150 are each placed in matrix material 160. The matrix material 160 may be as described for the matrix material 50 of FIG. 1.

Traditional white light emitting LEDs, comprising YAG phosphor and InGaN have a CRI of approximately 70-80. The LEDs of the present invention improve the CRI of the phosphor LED chip combination they are being added to. The term “improved color rendering index” is used herein with respect to the principles described with regard to FIG. 2 to indicate a color rendering index for an LED device comprising semiconductor nanocrystals that is greater than the light emitted by the mixture LED chip and powdered phosphor that they are used in combination with. Preferably the improved color rendering index would be greater than 85, more preferably greater than 90 and most preferably greater than 95.

The addition of the semiconductor nanocrystal complexes of the present invention do not substantially reduce the efficiency of the underlying LED chip/powdered phosphor combination. The term “do not substantially reduce the efficiency of the underlying LED chip” is used herein with respect to the principles described with regard to FIG. 2 to indicate that the addition of the nanocrystal complexes of the present invention decrease the deficiency of the underlying LED chip/phosphor combination by less than 30%, preferably less than 20%, more preferably less than 10%, most preferably less than 5%.

Preparation of LED Comprising Semiconductor Nanocrystal Complex

In step 310 the semiconductor nanocrystals are prepared and/or purchased. There are many known ways for the production of semiconductor nanocrystal. Additionally, semiconductor nanocrystals may be purchased for use in the present invention. The semiconductor nanocrystal complex prepared according to the procedure described below was found to work particularly well in the production of efficient and improved LED devices.

In step 320, the semiconductor nanocrystals are placed in a first matrix material. The semiconductor nanocrystal complexes prepared may be crashed out of solution and separated from the solvent they are prepared in. As discussed above, there are many optical epoxies and matrix materials that may be used for the creation of an efficient LED. In the example procedure, urethane/acrylate was added onto dried semiconductor nanocrystals. Many optically clear matrix materials may be used for the production of the LED devices of the present invention.

In step 330, the powdered phosphor is placed in a matrix material. This matrix material may be the same as or different to the matrix material for which the semiconductor nanocrystal complexes were placed into in step 320. For purposes of this example white light LED, a YAG-phosphor is mixed with urethane/acrylate. The yellow phosphor powder did not dissolve in the urethane/acrylate but it was evenly mixed into the matrix material. In the event that a single matrix material is desired comprising both the semiconductor nanocrystal complexes and the powdered phosphor, the powdered phosphor should be prepared in the same matrix material as the semiconductor nanocrystal complex is prepared in step 320.

In step 340, the matrix material comprising the semiconductor nanocrystal complexes and the matrix material comprising the powdered phosphor are mixed. This step is preferably performed in the event that the matrix material comprising the semiconductor nanocrystals and the matrix material comprising the powdered phosphor are the same material. It is appreciated that the matrix material comprising the semiconductor nanocrystal complexes and the matrix material comprising the powder phosphors may be separately dispersed onto the underlying chip (or onto a layer or layers overcoating the LED chip).

In step 350, the matrix material comprising the powdered phosphor and/or the semiconductor nanocrystal complex is optically coupled to the LED chip. Optically coupling refers to position the matrix materials on the chip such that at least a portion of the light emitted by the LED chip is absorbed by the matrix material comprising the powdered phosphor and/or the semiconductor nanocrystal complex. In the event that an LED device with a matrix material comprising both semiconductor nanocrystals and the powdered phosphor is desired, the material resulting from step 340 may be deposited directly onto the LED chip. In the event that a two or more layer LED is desired, wherein one layer comprises a matrix material comprising semiconductor nanocrystals and a second layer comprises a matrix material comprising a powdered phosphor, then step 340 need not be performed, and the materials resulting from steps 330 and step 320 may be deposited on top of the LED chip in either order. There are many known ways to deposit matrix materials onto LED chips and the methods described below are not intended to be limiting.

Example LED Devices

Highly fluorescent semiconductor nanocrystals were first prepared. The nanocrystals prepared by the below method have been found to be highly fluorescent and to be stable in matrix materials used for the production of LED devices. A recipe for semiconductor nanocrystal complex preparation, in accordance with an aspect of the present invention, is provided below.

I. Preparation of First Core CdSe Semiconductor Nanocrystals
1. 3.84 gram CdO, 11.86 gram oleic acid, and 1184 gram octadecene were loaded into 4-liter stainless reactor. Nitrogen was used to purge the reaction system for 10˜15 minutes;
2. In glove box, 5.056 gram Se:TBP solution (Se:TPB=1:3 by weight) was mixed with 600 gram octadecene, and the mixed solution was loaded into a one liter flask; this loaded flask was connected with the stainless reactor;
3. The solution in the reactor was heated up to 300˜380° C., followed by over-pressure injection of Se solution in the flask;
4. The reaction was stopped between 1 to 10 minutes by using ice-bath based on the desire particle size of CdSe nanocrystals.

II. Purification of the Core Semiconductor Nanocrystals
1. The above cooled down solution is mixed with 500 ml chloroform, and then centrifuged for 10 minutes at ˜3000 rpm. The supernatant is then mixed with 1000 ml methanol under strong stirring for 5 minutes;
2. The solution can then be loaded into 4-liter separation funnel and kept in the funnel stand for solution separation.
3. Once the solution was separated to two layers, completely release the bottom colorless solution through the funnel valve in the bottom;
4. The color solution in the separation funnel was transferred into a 3-liter container, then, was mixed with 500 ml chloroform, then 1000 ml methanol under strong stirring;
5. The mixed solution was loaded into the 4-liter separation funnel to repeat the separation procedure;
6. The purified dots solution is mixed with 1500 ml butanol and enough methanol, acetone to crash the dots from the solution. Centrifugation was used to separate the dots from the liquid. The clear, colorless supernatant was poured away, and the solid dots were dissolved into toluene;
7. The obtained dots in toluene solution was centrifuged at 4000 rpm for 10 minutes, and the supernatant dots solution was transferred into the container.

III. Preparation of Precursors for Shell Growth
1. 10.272 gram CdO, 200 ml oleic acid, and 600 ml octadecene were loaded into 2-liter glass reaction flask;
2. Nitrogen flow was used to purge the system for 10 to 15 minutes;
3. The mixture was heated up under stirring by heating mantle to 200° C. and was kept until all the CdO was dissolved into the solution to obtain an almost colorless clear solution.
4. The obtained clear solution was cooled down to room temperature.

IV. Shell Growth of CdSe Nanocrystals
1. 560 g Octadecene and 240 g hedecylamine were loaded into 3-liter reaction flask, then were purified at 100˜150° C. under vacuum for 60 minutes;
2. The sulphur precursor was prepared. The amount of cadmium, sulphur and diethyl zinc precursors for shell growth was calculated using known methods. Cd-precursor was used as they were made. (TMS)₂S and diethylzinc were mixed with octadecene based upon the amount of precursor determined above.
3. 50 ml CdSe core nanocrystals in toluene were introduced into above purified solvent at 50˜80° C. and the low boiling point solvent was pumped off by vacuum;
4. The solution was heated up to 120˜150° C., then, one third of calculated pre-prepared Cd-precursor solution and (TMS)₂S solution were added into the reaction flask by syringe pump, followed by aging for 30˜60 minutes.
5. Then, the solution in the reaction flask was heated up to 180˜220° C. and was kept at the certain temperature for 30˜60 minutes;
6. Another one third pre-prepared Cd-precursor solution and (TMS)₂S solution were injected into the reaction flask for further shell growth. After finished the injection, the solution was kept at the certain temperature for 30˜60 minutes.
7. Repeat the injection of the left one third pre-prepared Cd-precursor solution and (TMS)₂S solution, and aging procedure.
8. The solution in the reaction flask was cooled down to 120˜150° C. to stop the heating;
9. Then, ZnS shell precursors in solutions were injected through syringe pump. After finished the injection, the solution was allowed to age at the certain temperature for half of one hour.
10. Then, the solution was heated up to 180˜220° C., and was kept for half of one hour.
11. The heating was stopped, and the solution was cooled down to room temperature.
12. The semiconductor nanocrystal complex are isolated and then dissolved in toluene.

The population of semiconductor nanocrystals prepared above may emit light upon excitation at ˜620 nm. The quantum yield of the semiconductor nanocrystals prepared above has been measured at over 90%. The semiconductor nanocrystal complexes prepared above may be crashed out of solution and separated from the solvent they are prepared in. There are many ways to crash semiconductor nanocrystals out of solution. For the preparation of the example LED methanol was added to the prepared semiconductor nanocrystal. The volume of methanol added is about same as the volume of organic solvent containing semiconductor nanocrystals. In addition to crashing the nanocrystals out of solution with methanol only, a solution comprising methanol and acetone (2/1 ratio by volume) may be added to the vial. In either case, the solution will become cloudy as the semiconductor nanocrystals complex precipitate. Centrifuge the solution at high speed (˜20,000 rpm) for 15 minutes. The solution can be discarded and the precipitate may then be dried under nitrogen. To further remove the semiconductor nanocrystals from the solvent, the remnant solvent may be dried or heated using a vacuum oven. The vacuum oven temperature may be heated to about 50° C.

The semiconductor nanocrystals are then added to a matrix material. For the purpose of the example white light LED, urethane/acrylate was added onto the dried semiconductor nanocrystals. The solution was then sonicated for several hours to solvate the semiconductor nanocrystals in the urethane/acrylate matrix. After complete salvation, the urethane/acrylate matrix with the semiconductor nanocrystals is optically clear.

The powdered phosphor was then mixed with urethane/acrylate. For purposes of the example white light LED, a YAG-phosphor is mixed with urethane/acrylate. The yellow phosphor powder does not dissolve in the urethane/acrylate but it was evenly mixed into the matrix material.

The matrix material comprising the phosphor powder is mixed with the matrix material comprising the semiconductor nanocrystals. For the purpose of the example white light LED prepared using the above procedure, the final concentrations of urethane/acrylate are approximately 150-600 mg/ml for YAG-Phosphor, and approximately 0.1-1 mg/ml for the semiconductor nanocrystals. Depending on the underlying LED chip and the powdered phosphor used, the amount of semiconductor nanocrystals to achieve the desired CRI may vary.

The mixed matrix materials are delivered on an LED chip. The volume of urethane/acrylate (with phosphors) delivered on the chip was 0.1-5 micro-liter, which can make 50 □m to 2000 □m film on the LED die. The LED chip used in the example is a TGEVID-466 nm device. The phosphor layer is cured using UV source “Green Spot”. On top of the phosphor layer, pure urethane/acrylate is used to encapsulate the phosphor and LED chip. The curing of the matrix material requires a high intensity UV source if the curing is done in air. Alternatively, a lower energy source can be used if the curing is done in a relatively oxygen-free environment.

A second white light emitting LED may be made with high efficiency and high CRI using the materials prepared above. In the second example LED, two populations of semiconductor nanocrystals may be prepared in the matrix material as discussed above. In the second example, an ˜610 nm emitting CdSe semiconductor nanocrystal complex and an ˜630 nm emitting semiconductor nanocrystal were prepared in the urethane/acrylate, as described above. This matrix material is then mixed with the phosphor powder, as described above, and deposited onto an LED chip, as described above.

A third white light LED device may be made as follows. In this device, the matrix material comprising the semiconductor nanocrystal complexes and the matrix material comprising the powdered phosphor were made identical to the first example LED device. However, rather than mixing the materials together to form a single matrix, the materials were deposited separately, in the amounts described above, onto an LED chip. This type of LED device may be preferred in the event that two separate matrix materials are used comprising the semiconductor nanocrystal complexes and the powdered phosphor.

A fourth type of white emitting LED device may be made as follows. Two populations of semiconductor nanocrystals may be prepared as described above. These two populations of nanocrystal complexes may be the same as that described in the second type of LED. The nanocrystals may be dispersed in matrix materials as described above. Additionally, the powdered phosphor may be dispersed in a second matrix material as described above. The two matrix materials, in any order, may then be deposited on an LED chip in the desired amount as described above.

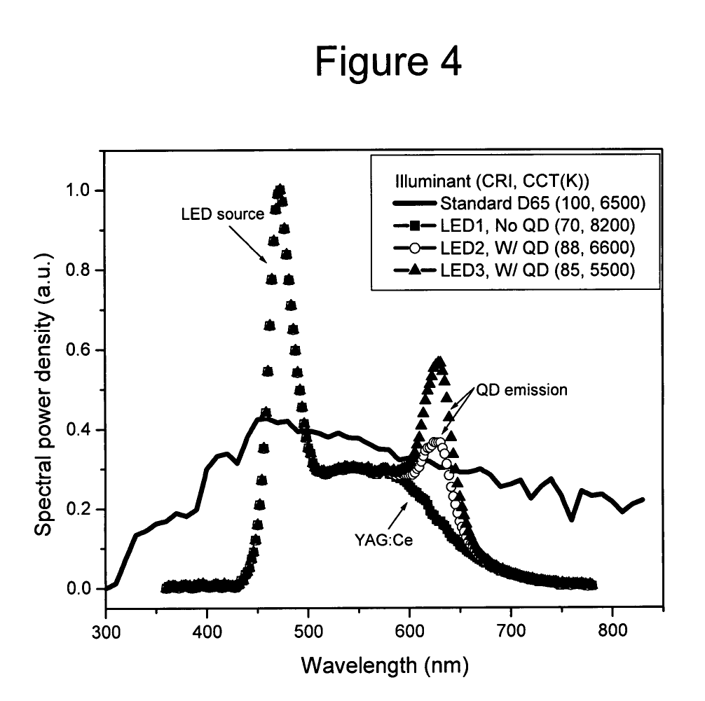

FIG. 4 represents a graph of the emission spectrum of three LED devices in comparison with a standard black body emission. The black line represents the emission spectrum of a daylight lamp at a color temperature of 6,500 K. This lamp represents the emission spectrum of sunlight at noon. As can be seen on the graph, sunlight comprises portions of all wavelengths of visible light. Sunlight has a color rendering index of 100. LED1 represents a white light LED comprising cerium doped YAG phosphor on a blue source LED chip. The emission spectrum decreases at below 600 nm. The emission of the Cerium doped YAG is represented by the emission at between 500 nm and 600 nm. The underlying LED chip used for the purposes of the experiment was a TGEVID-466 nm chip. This red portion of the color spectrum is essentially missing from the white light emitting LED devices that do not contain semiconductor nanocrystal complexes. Additionally, the color temperature is 8200 K, which is a “cool” temperature when compared to the temperature of standard sunlight.

Many applications desire “warmer” whites meaning whites of a lower color temperature. Incandescent bulbs used for home lighting often have color temperatures as low as 3500 K. LED2 device shows an emission spectrum of an LED comprising ˜0.175 μg of cerium doped YAG phosphor and ˜0.21 μg of 620 nm emitting semiconductor nanocrystals deposited in 0.7 μl of urethane/acrylate, made as described above, and deposited on a TGEVID-466 nm chip. As indicated in FIG. 4, the semiconductor nanocrystal complexes allow for emission of red light. The device emission results in a color rendering index of 88 and a color temperature of 6600 K. Thus, the addition of the semiconductor nanocrystals improves the color rendering index of the device while “warming” the emission.

LED3 device shows an emission spectrum of an LED comprising ˜0.175 μg of cerium doped YAG phosphor and ˜0.35 μg of 620 emitting semiconductor nanocrystals deposited in 0.7 μl of urethane/acrylate, made as described above, and deposited on a TGEVID-466 nm chip. As indicated in FIG. 4, the semiconductor nanocrystal complexes allow for emission of red light. The device emission results in a color rendering index of 85 and a color temperature of 5500 K.

In addition to improving the color rendering index of the powdered phosphors generated white light, the addition of the semiconductor nanocrystal complexes did not substantially reduce the efficiency of the device. The efficiency of the cerium doped YAG phosphor atop the led chips in LED1 was measured to be ˜34 lumens/watt while in LED2 and LED3, the luminescence efficiency was measured to be ˜30 lumens/watt.

The foregoing description and example have been set forth merely to illustrate the invention and are not intended as being limiting. Each of the disclosed aspects and embodiments of the present invention may be considered individually or in combination with other aspects, embodiments, and variations of the invention. In addition, unless otherwise specified, none of the steps of the methods of the present invention are confined to any particular order of performance. Modifications of the disclosed embodiments incorporating the spirit and substance of the invention may occur to persons skilled in the art and such modifications are within the scope of the present invention. Furthermore, all references cited herein are incorporated by reference in their entirety.

We claim:

1. A white light light emitting diode (LED) comprising:
an LED chip that emits light at a first wavelength;
a semiconductor nanocrystal complex that absorbs at least a first portion of the light emitted by the LED chip and emits light at a second wavelength; and
a powdered phosphor that absorbs at least a second portion of the light emitted by the LED chip and emits light at a third wavelength.

2. The white light LED of claim 1, wherein the semiconductor nanocrystal complex and the powdered phosphor are placed into a matrix material.

3. The white light LED of claim 2, wherein the semiconductor nanocrystal complex comprises two populations of semiconductor nanocrystals.

4. The white light LED of claim 3, wherein:
a first population of semiconductor nanocrystals emits light at the second wavelength; and
a second population of semiconductor nanocrystals emits light at a fourth wavelength.

5. The white light LED of claim 1, wherein the powdered phosphor is placed into a first matrix material and the semiconductor nanocrystal complex is placed into a second matrix material.

6. The white light LED of claim 5, wherein:
the powdered phosphor is deposited as a first layer onto the LED chip; and
the semiconductor nanocrystal complex is deposited as a second layer onto the LED chip.

7. The white light LED of claim 6, wherein the first layer is deposited between the LED chip and the second layer.

8. The white light LED of claim 6, wherein the semiconductor nanocrystal complex comprises two populations of semiconductor nanocrystals.

9. The white light LED of claim 6, further comprising a second semiconductor nanocrystal complex deposited as a third layer onto the LED chip.

10. The white light LED of claim 1, wherein the second wavelength is longer than the first wavelength.

11. The white light LED of claim 1, wherein the third wavelength is longer than the first wavelength.

12. A method of forming a white light light emitting diode (LED) comprising:
depositing an LED chip that emits light at a first wavelength;
forming a semiconductor nanocrystal complex that absorbs at least a first portion of the light emitted by the LED chip and emits light at a second wavelength; and
depositing the semiconductor nanocrystal complex and a powdered phosphor over the LED chip, wherein the powdered phosphor absorbs at least a second portion of the light emitted by the LED chip and emits light at a third wavelength.

13. The method of claim 12, further comprising mixing the semiconductor nanocrystal complex and the powdered phosphor into a matrix material.

14. The method of claim 13, wherein forming the semiconductor nanocrystal complex further comprises mixing first and second populations of semiconductor nanocrystals together.

15. The method of claim 12, further comprising mixing the powdered phosphor into a first matrix material and the semiconductor nanocrystal complex into a second matrix material.

16. The method of claim 15, further comprising:
depositing the powdered phosphor and the first matrix material as a first layer over the LED chip; and
depositing the semiconductor nanocrystal complex and the second matrix material as a second layer over the LED chip.

17. The method of claim 16, further comprising depositing the first layer between the LED chip and the second layer.

18. The method of claim 12, further comprising depositing a second semiconductor nanocrystal complex over the LED chip.
